(19) United States
(12) Patent Application Publication
(10) Pub. No.: US 2012/0052684 A1
(43) Pub. Date: Mar. 1, 2012

(54) METHOD OF MANUFACTURING SEMICONDUCTOR DEVICE

(75) Inventor: Yuichi YOSHIDA, Nagoya (JP)

(73) Assignee: Kabushiki Kaisha Toshiba, Tokyo (JP)

(21) Appl. No.: 13/053,704

(22) Filed: Mar. 22, 2011

(30) Foreign Application Priority Data
Aug. 27, 2010 (JP) 2010-190763

(51) Int. Cl. H01L 21/311

(52) U.S. Cl. 438/702; 257/E21.249

(57) ABSTRACT

A method of manufacturing a semiconductor device is disclosed. The method includes preparing an underlying structure; forming a protective film above the underlying structure; forming a trench into the protective film and the underlying structure; filling the trench with a fill material; planarizing the fill material such that the protective film is exposed; forming a sacrificial film above the fill material and the protective film; and reactive ion etching the sacrificial film and the fill material. The fill material is selectively etched back within the trench.

### CROSS-REFERENCE TO RELATED APPLICATION(S)

This application is based upon and claims the benefit of priority from Japanese Patent Application No. 2010-190763, filed on, Aug. 27, 2010 the entire contents of which are incorporated herein by reference.

### FIELD

Exemplary embodiments disclosed herein generally relate to a method of manufacturing a semiconductor device.

### BACKGROUND

In semiconductor manufacturing, selective etching has been carried out in which a given material is selectively etched relative to other materials in a feature. For instance, in a feature including different types of insulating films made of materials such as a silicon oxide film and a silicon nitride film, the silicon oxide film may be selectively etched relative to the silicon nitride film or vice versa typically by RIE (Reactive Ion Etching). In such case, the film etched with relatively greater selectivity may be referred to as an etching film or a processing film, whereas the film etched with relatively less selectivity or left substantially unetched may be referred to as an unetched film or an unprocessed film.

Even when a selective etch condition is applied, unetched film is, nevertheless, slightly etched. Thus, when the unetched film is used as a protective film, there were instances where the unetched film was etched away by the time the specified amount of etching of the etching film was completed. The protective film, when etched away, fails to protect the underlying structure, thereby unwantedly subjecting the underlying structure to etching.

### BRIEF DESCRIPTION OF THE DRAWINGS

FIG. 1 is a partial equivalent circuit representation of a memory cell array of a NAND flash memory according to a first exemplary embodiment of the present disclosure;

FIG. 2 is a schematic plan view partially illustrating a layout of a memory cell region;

FIG. 3A is a schematic vertical cross-sectional view taken along line 3A-3A in FIG. 2;

FIG. 3B is a schematic vertical cross-sectional view taken along line 3B-3B in FIG. 2;

FIGS. 4, 5, 6, 7, 8, 9, 10, 11, 12, and 13, each schematically illustrates a vertical cross-sectional view of 1 out of 10 manufacturing phases of the portion taken along line 3B-3B of FIG. 2; and

FIG. 14 schematically illustrates a second exemplary embodiment of the present disclosure and provides a vertical cross-sectional view of a manufacturing phase of the portion taken along line 3B-3B of FIG. 2.

### DETAILED DESCRIPTION

In one exemplary embodiment, a method of manufacturing a semiconductor device is disclosed. The method includes preparing an underlying structure; forming a protective film above the underlying structure; forming a trench into the protective film and the underlying structure; filling the trench with a fill material; planarizing the fill material such that the protective film is exposed; forming a sacrificial film above the fill material and the protective film; and reactive ion etching the sacrificial film and the fill material. The fill material is selectively etched back within the trench.

Exemplary embodiments are described hereinafter with references to the accompanying drawings to provide illustrations of the features of the exemplary embodiments. Elements that are identical or similar are represented by identical or similar reference symbols across the figures and are not redescribed. The drawings are not drawn to scale and thus, do not reflect the actual measurements of the features such as the correlation of thickness to planar dimensions and the relative thickness of different layers.

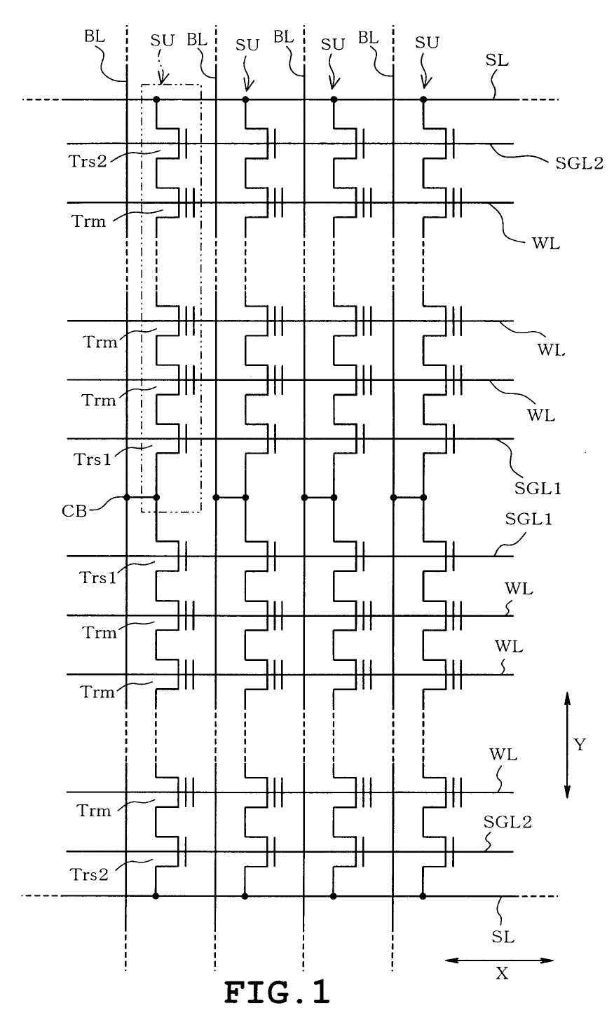

FIG. 1 is a partial equivalent circuit representation of a memory cell array formed in the memory cell region of a NAND flash memory according to a first exemplary embodiment. As can be seen in FIG. 1, the memory cell array is a collection of units of NAND cells also referred to as NAND cell unit Su arranged in rows and columns. NAND cell unit SU comprises a multiplicity of series connected memory cell transistors Trm, such as 32 in number, situated between a pair of select gate transistors Trs1 and Trs2. The neighboring memory cell transistors Trm within NAND cell unit SU share their source/drain regions.

Still referring to FIG. 1, the X-direction aligned memory cell transistors Trm are interconnected by common word line WL, whereas the X-direction aligned select gate transistors Trs1 are interconnected by common select gate line SGL1 and likewise, the X-direction aligned select gate transistors Trs2 are interconnected by common select gate line SGL2. The drain of each select gate transistor Trs1 is coupled to bit line BL by way of bit line contact CB. Bit line BL extends in the Y direction orthogonal to the X direction. The source of select gate transistor Trs2 is coupled to source line SL extending in the X-direction. As apparent from FIG. 1, the X direction indicates the direction in which word line WL extends or the width direction of the gate, whereas the Y direction indicates the direction in which bit line BL extends or the length direction of the gate.

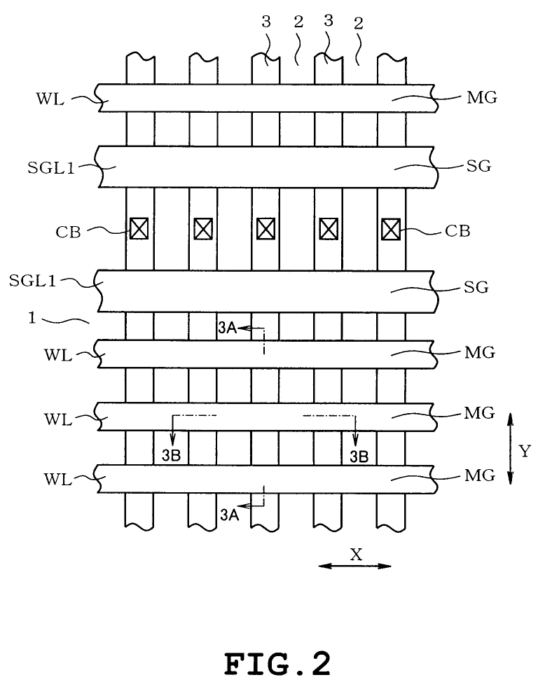

FIG. 2 provides a planar layout of memory cell region in part. As shown, multiplicity of element isolation regions employing a shallow trench isolation scheme represented as STI 2 run in the Y direction of silicon substrate 1, or more generally, the semiconductor substrate, to isolate active regions 3 by a predetermined space interval in the X direction. Multiplicity of X-directional word lines WL of memory cell transistors Trm run above STI 2 and active regions 3 so as to be orthogonal to STI 2 and active regions 3 extending in the Y direction and thus, appear as multiplicity of rows aligned in the Y direction in FIG. 2.

Still referring to FIG. 2, in active region 3 located between a couple of X-directional select gate lines SGL1 that are each connected to select gate transistors, bit line contact CB is formed. Bit line contact CB is coupled to an overlying bit line BL running in the Y direction though not shown in detail in FIG. 2. Gate electrode MG of a memory cell transistor is formed in active region 3 where word line WL crosses over, whereas gate electrode SG of a select gate transistor is formed in active region 3 where select gate line SGL1/SGL2 crosses over.

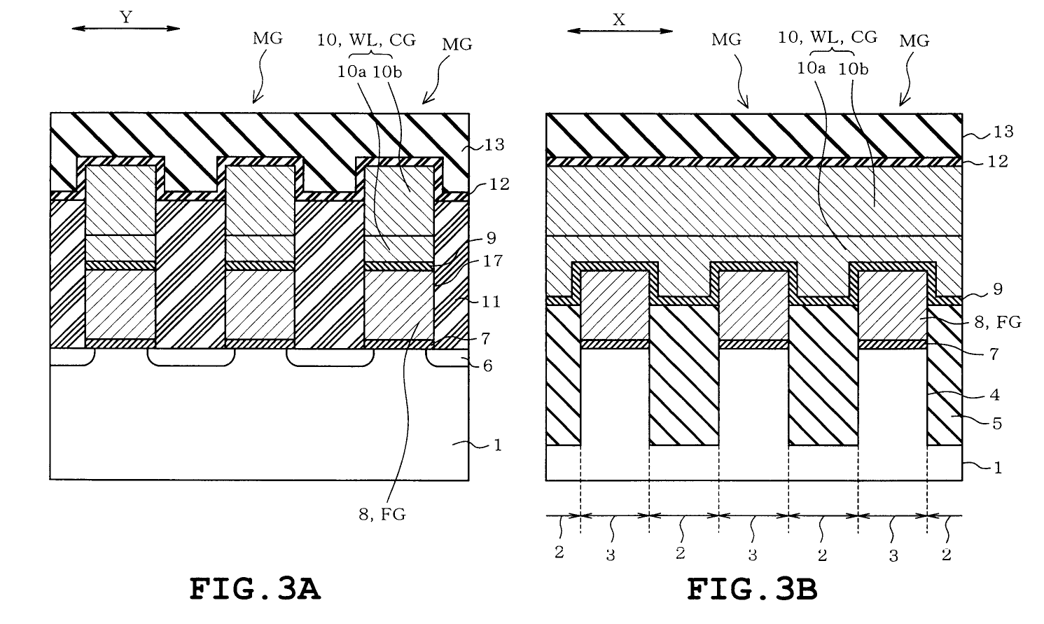

FIGS. 3A and 3B are schematic vertical cross sectional views taken along lines 3A-3A and 3B-3B of FIG. 2. More specifically, FIG. 3A is a cross section of the memory cell transistor taken along bit line BL or the Y direction to show the cross section of the gate electrode MG, whereas FIG. 3B is a cross section taken along word line WL or the X direction to provide an alternative view.

As can be seen in FIG. 3B, multiplicity of element isolation trenches 4 are formed into a p-conductive-type substrate 1. As viewed in FIG. 3B, trenches 4 are aligned in the X direction to isolate active regions 3 in the X direction. Element isolation trench 4 is filled with element isolation insulating film 5 to form STI 2.

A memory cell transistor Trm comprises an n conductive type diffusion layer 6 formed in silicon substrate 1, gate insulating film 7 formed above silicon substrate 1, and gate electrode MG formed above gate insulating film 7. Gate electrode MG comprises floating gate electrode FG serving as a charge storing layer, interelectrode insulating film 9 formed over floating gate electrode FG, and control gate electrode CG formed over interelectrode insulating film 9. Diffusion layer 6 is formed in the surface layer of silicon substrate 1 so as to be located at both sides of gate electrode MG and serves as a source/drain region.

Gate insulating film 7 is formed above silicon substrate 1 and more specifically above active regions 3 of silicon substrate 1. Gate insulating film 7 typically comprises a silicon oxynitride film. Floating gate electrode FG typically comprises a polycrystalline silicon layer 8 serving as a conductive layer and is doped with impurities such as phosphorus. Interelectrode insulating film 9 is formed along the upper surface of element isolation insulating film 5, the upper sidewall of floating gate electrode FG, and the upper surface of floating gate electrode FG. Interelectrode insulating film 9, serving as an insulating film between the electrodes, also serves as an interpoly film and inter conductive layer film. Interelectrode insulating film typically takes a laminate structure of silicon oxide film/silicon nitride film/silicon oxide film known as an ONO film with each layer typically being 3 nm to 10 nm thick.

Control gate electrode CG comprises conductive layer 10 serving as word line WL of memory cell transistor Trm. Conductor layer 10 comprises polycrystalline silicon layer 10a and silicide layer 10b formed immediately on top of polycrystalline silicon layer 10a. Polycrystalline silicon layer 10a is doped with impurities such as phosphorus and silicide layer 10b which forms a silicide with either tungsten (W), cobalt (Co), nickel (Ni) or other such metals. Silicide layer 10b, according to the first exemplary embodiment, comprises nickel silicide (NiSi). In an alternative exemplary embodiment, conductive layer 10 may be configured by silicide layer 10b alone.

FIG. 3A shows a Y-direction alignment of gate electrode MG of memory cell transistor. As shown, each gate electrode MG is electrically isolated by trench 17 which is filled with inter-memory-cell insulating film 11. Inter-memory-cell insulating film 11 may comprise a silicon oxide film, employing TEOS (Tetraethyl orthosilicate) oxide film, or an insulating film with low dielectric constant.

Over the upper surface of inter-memory-cell insulating film 11 and sidewall and the upper surface of control gate electrode CG, liner insulating film 12 is formed which comprises, for instance, a silicon nitride film. Above liner insulating film 12, interlayer insulating film 13 is formed that comprises, for instance, a silicon oxide film. Liner insulating film 12 keeps oxidation agents away from control gate electrode CG during formation of interlayer insulating film 13 which comprises a silicon oxide film. Such feature is particularly advantageous in preventing increase in the resistance of word line WL which is typically caused by the oxidation of silicide layer 10b. Further, liner insulating film 12 is lined along the control gate electrode CG gaps but does not fill them. Thus, increase in parasitic capacitance can be suppressed which in turn reduces the possibility of interconnect delay.

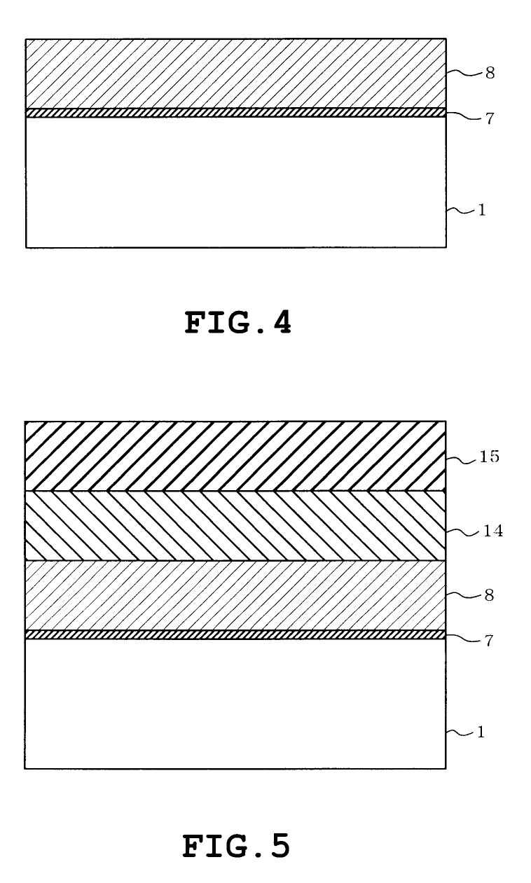

Next, a description will be given on the method of manufacturing a NAND flash memory device according to the first exemplary embodiment with reference to FIGS. 4 to 13. FIGS. 4 to 13 illustrate the cross sections taken in FIG. 3B at different stages of the manufacturing process flow.

Referring first to FIG. 4, gate insulating film 7 is formed above the surface of p-conductive-type silicon substrate 1 or above a silicon substrate having a p-conductive-type well formed in its surface layer. Gate insulating film 7 may comprises a silicon oxynitride film made by a combination of known thermal oxidation and thermal nitridation schemes. Then, above gate insulating film 7, doped polycrystalline silicon layer 8 is formed by LPCVD (Low Pressure Chemical Vapor Deposition). Doped polycrystalline silicon layer 8 may be doped with impurities such as phosphorus (P).

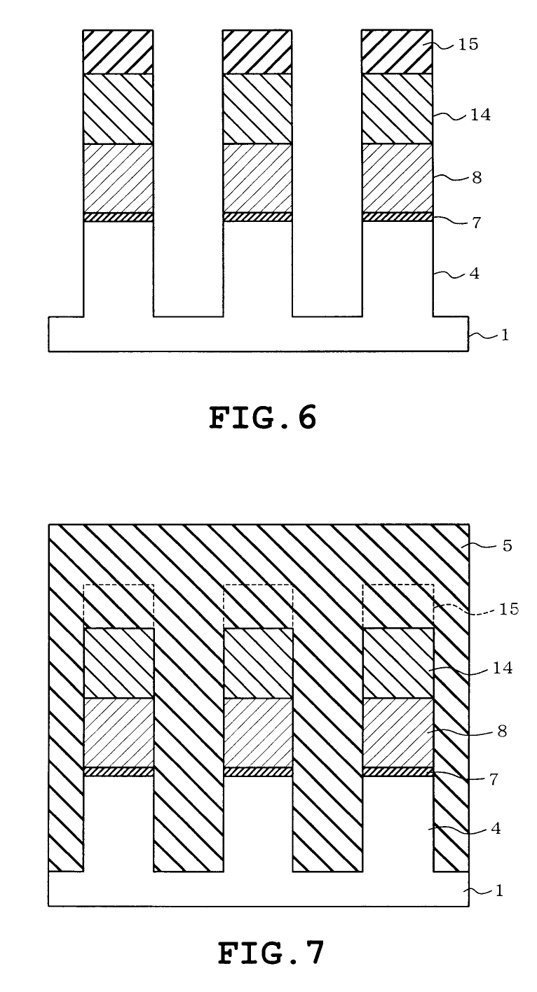

Then, as shown in FIG. 5, silicon nitride film 14 and silicon oxide film 15 are formed in the listed sequence above doped polycrystalline silicon layer 8 by CVD (Chemical Vapor Deposition). Then, a photoresist not shown is coated over silicon oxide film 15 and thereafter patterned by lithographic development. Using the patterned photoresist as a mask, silicon oxide film 15 is etched by RIE (Reactive Ion Etching). After RIE, photoresist is removed. Then, using silicon oxide film 15 as a mask, silicon nitride film 14, doped polycrystalline silicon layer 8 (floating gate electrode FG), gate insulating film 7, and silicon substrate 1 are etched to form trench 4 providing element isolation as shown in FIG. 6.

Then, as shown in FIG. 7, trench 4 is typically overfilled with silicon oxide film 5, later also referred to as element isolation insulating film 5, by CVD or coating technique. Silicon oxide film 15 used as a mask in forming trench 4 and siliccn oxide film 5 filled in trench 4 are collectively represented as silicon oxide film 5 in FIG. 7.

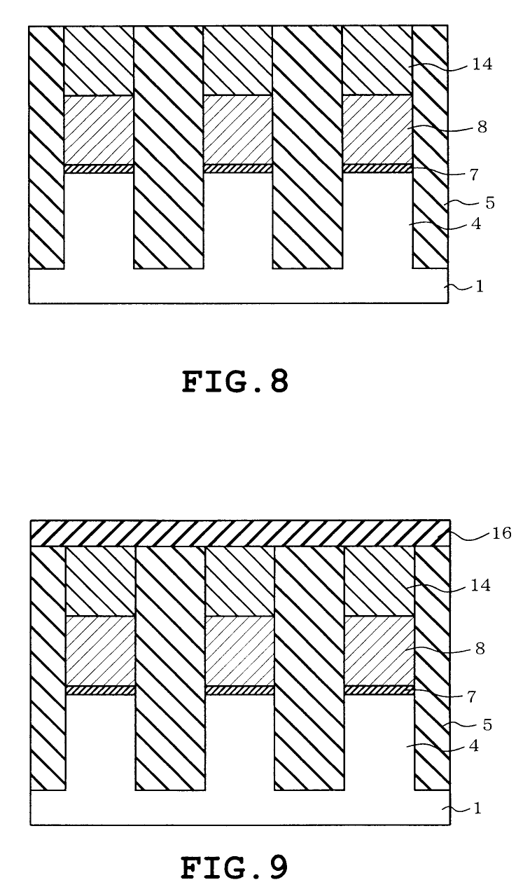

Referring now to FIG. 8, the feature is planarized by CMP (Chemical Mechanical Polishing) until silicon nitride film 14 is exposed. Silicon oxide film 5 filled in trench 4 now serves as element isolation insulating film 5. In the above described feature, element isolation insulating film (silicon oxide film) 5 may also be referred to as an etching film, whereas silicon nitride film 14 may be referred to as an unetched film.

Planarization is followed by selective RIE to etch back element isolation insulating film 5 filled between the adjacent floating gate electrodes FG (polycrystalline silicon layer 8) such that element isolation insulating film 5 is lowered in elevation within trench 4. The first exemplary embodiment introduces the following step prior to the selective RIE. As shown in FIG. 9, silicon oxide film 16 is formed above silicon oxide (element isolation insulating film) 5 and silicon nitride film 14 by CVD (Chemical Vapor Deposition). Silicon oxide film 16 serves as a sacrificial film.

Then, silicon oxide film 5 is selectively etched by RIE as the result of the faster etch rate relative to silicon nitride film 14. In the RIE, plasma comprising CF (Fluorocarbon) based gas is generated by the mixture of: C₄F₆ gas supplied at the flow rate of 10 sccm, Ar gas at 600 sccm, and O₂ gas at 10 sccm.

RIE executed with the foregoing etch recipe results in a 6:1 etching rate between silicon oxide film 5 and silicon nitride film 14 provided that the reaction gases are sufficiently dissociated. Substantial dissociation is not achieved until prescribed time, e.g. 5 seconds, has elapsed from the start of electric discharge, that is, from the supply of electricity. Thus, etching executed within the prescribed time period only achieves an etch rate of approximately 1:1 between silicon oxide film 5 and silicon nitride film 14 because of the insufficient dissociation, thereby failing to selectively etch silicon oxide film 5 relative to silicon nitride film 14 in the desired selectivity.

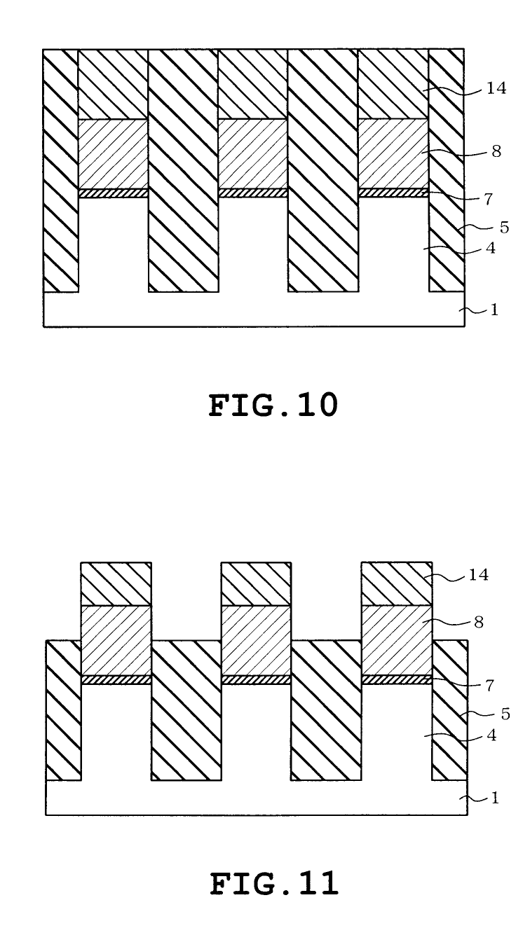

FIG. 10 shows the resulting feature after the elapse of the prescribed time, i.e., 5 seconds, from the supply of electricity for plasma generation. As shown, silicon oxide film 16 is fully or almost fully etched away. Now that the reaction gases are sufficiently dissociated, RIE progresses with the 6:1 etch rate of silicon oxide film 5 to silicon nitride film 14. As a result, silicon oxide film 5 is etched back to the desired elevation as exemplified in FIG. 11. Though silicon nitride film 14 etches slightly during the selective RIE of silicon oxide film 5, most of it remains sufficiently unetched and thus, provides protection to the underlying polycrystalline silicon layer 8 as can be seen in FIG. 11.

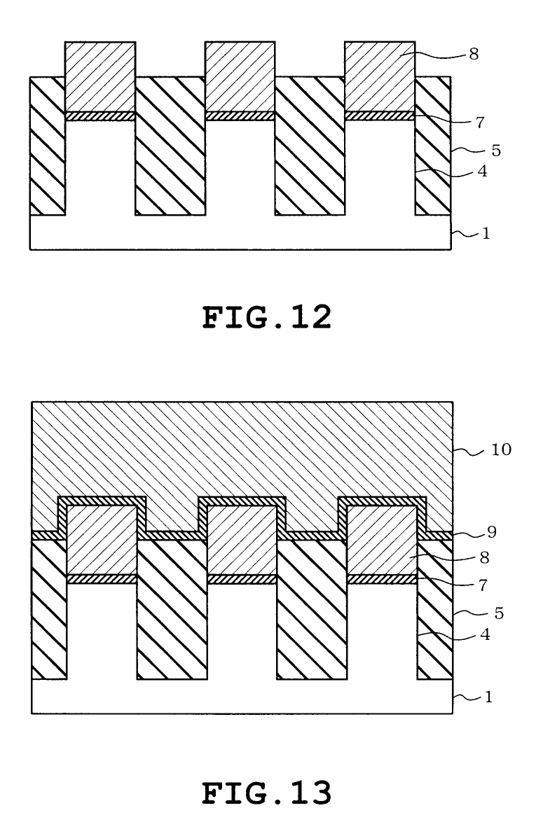

Then, silicon nitride film 14 remaining above polycrystalline silicon layer 8 is selectively etched away by wet etching to obtain the structure shown in FIG. 12.

Next, interelectrode insulating film 9 is formed above the exposed surface of polycrystalline silicon layer 8 and above element isolation insulating film 5 as shown in FIG. 13. Interelectrode insulating film 9 may be a single layer of high-dielectric-constant insulating film or multiple layers of various films. The multiple layers may comprise a laminate of: silicon oxide film/high-dielectric-constant insulating film/silicon oxide film; silicon oxide film/silicon nitride film/silicon oxide film; or silicon nitride film/silicon oxide film/silicon nitride film/silicon oxide film/silicon nitride film formed by known processes. Then, above interelectrode insulating film 9, doped polycrystalline silicon layer 10 also referred to as conductive layer 10 serving as control gate electrode CG is formed by CVD to obtain the structure shown in FIG. 13. Doped polycrystalline silicon layer 10 may be doped with impurities such as phosphorus (P).

Thereafter, trenches 17 shown in FIG. 3A are formed for electrode isolation to obtain a multiplicity of gate structures by known processes. Then, impurities are doped into silicon substrate 1 at the inner bottom surface of trench 17 to form diffusion layer 6. Trench 17 is thereafter filled with inter-memory-cell insulating film 11 which is subsequently planarized and lowered in elevation. Then, nickel silicide (NiSi) layer 10b is formed at the upper portion of polycrystalline silicon layer (conductive layer) 10 followed by formation of liner insulating film 12 and interlayer insulating film 13 as shown in FIG. 3A.

According to the above described first exemplary embodiment, silicon oxide film 16 is formed above silicon oxide film (element isolation insulating film) 5 and silicon nitride film 14 as shown in FIG. 9 prior to selective RIE etch back of element isolation insulating film 5 in which element isolation insulating film 5 filled between the isolated polycrystalline silicon layers 8 serving as floating gate electrode FG is lowered in elevation. As described earlier, sufficient dissociation of reaction gases supplied into the reaction chamber is not achieved until a prescribed time, e.g. 5 seconds, has elapsed from the start of electric discharge, that is, from the supply of electricity. Thus, etching executed within the prescribed time period only achieves an etch rate of approximately 1:1 between silicon oxide film 5 and silicon nitride film 14. Thus, the provision of a sacrificial silicon oxide film 16 protects silicon nitride film 14 during the prescribed time period to allow the subsequent selective RIE to progress with faster etch rate for silicon oxide film 5 relative to silicon nitride film 14, thereby relatively reducing the etch amount of silicon nitride film 14. The first exemplary embodiment thus, successfully prevents complete removal of silicon nitride film 14 during the RIE.

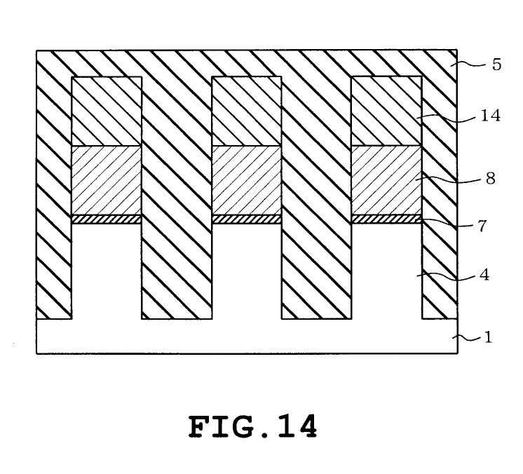

FIG. 14 illustrates a second exemplary embodiment. The elements that are identical with the first exemplary embodiment are represented by identical reference symbols. In the first exemplary embodiment, silicon oxide film 5 filled in trench 4 as shown in FIG. 7 is thereafter planarized by CMP until the upper surface of silicon nitride film 14 is exposed as shown in FIG. 8. The second exemplary embodiment takes the following alternative approach. After filling trench 4 with silicon oxide film 5 as shown in FIG. 7, silicon oxide film 5 is planarized by CMP such that a predetermined thickness of silicon oxide film 5 remains above the upper surface of silicon nitride film 14 as shown in FIG. 14. The remaining silicon oxide film 5 is controlled to a thickness substantially equal to the thickness of silicon oxide film 16 of the first exemplary embodiment by monitoring its thickness during CMP using a thickness monitoring element. The planarization is followed by selective etching as was the case in the first exemplary embodiment.

Apart from the above described difference, the methodology employed in the second exemplary embodiment is the same as the first exemplary embodiment and thus, achieves the operation and effect similar to those of the first exemplary embodiment. Because the second exemplary embodiment is arranged to leave a predetermined thickness of silicon oxide film 5 above the upper surface of silicon nitride film 14 in the planarization of silicon oxide film 5 filled in trench 4, formation of silicon oxide film 16 carried out in the first exemplary embodiment can be eliminated to advantageously reduce the number of process steps.

The first and the second exemplary embodiments described above may be modified as follows.

Both silicon oxide film 5 serving as the fill material being selectively etched and silicon oxide film 16 serving as the sacrificial film in the first and the second exemplary embodiments may comprise either TEOS (tetraethyl orthosilicate), PSZ (polysilazane), BPSG (boron phosphorus silicate glass), PSG (phosphorus silicate glass) or silane oxide film. Silicon nitride film 14 serving as the protective film may be replaced by silicon carbide film (SiC) or be used in conjuction with silicon carbide film.

In the first and the second exemplary embodiments, silicon oxide film 5 was used as the fill material being selectively etched, whereas silicon nitride film 14 was used as the protective film. Alternatively, silicon nitride film may be used as the fill material being selectively etched, and silicon oxide film such as TEOS, PSZ, BPSG, PSG, and silane oxide film may be used as the protective film. In such case, silicon nitride film is used as the sacrificial film. In the above arrangement, plasma is generated in the gas mixture of: C₄F₆ gas supplied at the flow rate of 50 sccm, Ar gas at 100 sccm, and O₂ gas at 50 sccm.

In the first exemplary embodiment silicon oxide film 16 which may be any one of TEOS, PSZ, BPSG, PSG, and silane oxide was employed as the sacrificial film. However, silicon nitride film may be employed instead. Further, silicon oxide film 16 need not be a single layer oxide film but may be a laminate including two or more of the above described silicon oxide films.

The first and the second exemplary embodiments were directed to a NAND flash memory application, in which the present disclosure was applied to the etch back of the element isolation insulating film (silicon oxide film) 5 filled in element isolation trench 4. The present disclosure may also be applied to a process of forming a buried strap for electrically connecting a storage node electrode and a cell-transistor diffusion layer of a DRAM, in which resist or silicon containing material buried in a trench formed into a semiconductor (silicon) substrate are etched back. In such case, resist or silicon containing material serves as the fill material and a silicon nitride film formed above the semiconductor substrate for substrate protection serves as the protective film. The present disclosure may also be applied to a process of forming a damascene interconnect in which a metal interconnect layer being filled in an interconnect trench defined through a laminate interlayer insulating film of low-dielectric-constant insulating film and silicon oxide film is etched back. In such case, the metal layer serves as the fill material and the silicon oxide film serves as the protective film for protecting the underlying low-dielectric-constant insulating film. In the recess defined by etching back the metal layer, a top barrier film may be formed to prevent diffusion of metal contained in the interconnect fill.

As set forth above, the method of manufacturing a semiconductor device according to the foregoing exemplary embodiments reduces the amount of removal of the protective film when selectively etching the fill material relative to the protective film.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
preparing an underlying structure;
forming a protective film above the underlying structure;
forming a trench into the protective film and the underlying structure;
filling the trench with a fill material;
planarizing the fill material such that the protective film is exposed;
forming a sacrificial film above the fill material and the protective film; and
reactive ion etching the sacrificial film and the fill material, the fill material being selectively etched back within the trench.

2. The method according to claim 1, wherein the fill material comprises a silicon oxide film and the protective film comprises at least one of a silicon nitride film and a silicon carbide film.

3. The method according to claim 1, wherein selectively etching back the fill material employs a fluorocarbon gas based plasma.

4. The method according to claim 1, wherein planarizing the fill material employs chemical mechanical polishing.

5. The method according to claim 1, wherein the fill material comprises a silicon nitride film and the protective film comprises a silicon oxide film.

6. The method according to claim 5, wherein the silicon oxide film comprises one selected from the group of tetraethyl orthosilicate, polysilazane, boron phosphorus silicate glass, phosphorus silicate glass, and silane oxide film.

7. The method according to claim 1, wherein the fill material comprises a silicon oxide film, the protective film comprises at least one of a silicon nitride film and a silicon carbide film, and the sacrificial film comprises at least one of the silicon oxide film and the silicon nitride film.

8. The method according to claim 7, wherein the silicon oxide film serving as the fill material and the sacrificial film comprises one selected from the group of tetraethyl orthosilicate, polysilazane, boron phosphorus silicate glass, phosphorus silicate glass, and silane oxide film.

9. The method according to claim 1, wherein the underlying structure comprises a silicon substrate, a gate insulating film formed above the silicon substrate, and a charge storing layer formed above the gate insulating film.

10. The method according to claim 1, wherein the underlying structure comprises a silicon substrate, the protective film comprises a silicon nitride film formed above the silicon substrate, and the fill material filled in the trench comprises a resist or a silicon containing material.

11. The method according to claim 1, wherein the underlying structure comprises a low-dielectric-constant insulating film, the protective film comprises a silicon oxide film, the trench comprises an interconnect trench, and the fill material comprises a metal layer.

12. A method of manufacturing a semiconductor device, comprising:
preparing an underlying structure;
forming a protective film above the underlying structure;
forming a trench into the protective film and the underlying structure;
filling the trench with a fill material;
planarizing the fill material such that a predetermined thickness of the fill material remains above the protective film; and
after planarizing, reactive ion etching the fill material such that the fill material is selectively etched back within the trench.

13. The method according to claim 12, wherein the fill material comprises a silicon oxide film and the protective film comprises at least one of a silicon nitride film and a silicon carbide film.

14. The method according to claim 13, wherein the silicon oxide film comprises one selected from the group of tetraethyl orthosilicate, polysilazane, boron phosphorus silicate glass, phosphorus silicate glass, and silane oxide film.

15. The method according to claim 12, wherein selectively etching back the fill material employs a fluorocarbon gas based plasma.

16. The method according to claim 12, wherein planarizing the fill material employs chemical mechanical polishing in which thickness of the fill material above the protective film is monitored by a thickness monitoring element.

17. The method according to claim 12, wherein the fill material comprises a silicon nitride film and the protective film comprises a silicon oxide film.

18. The method according to claim 17, wherein the silicon oxide film comprises one selected from the group of tetraethyl orthosilicate, polysilazane, boron phosphorus silicate glass, phosphorus silicate glass, and silane oxide film.

19. The method according to claim 12, wherein the underlying structure comprises a silicon substrate, a gate insulating film formed above the silicon substrate, and a charge storing layer formed above the gate insulating film.

20. The method according to claim 12, wherein the underlying structure comprises a silicon substrate, the protective film comprises a silicon nitride film formed above the silicon substrate, and the fill material filled in the trench comprises a resist or a silicon containing material.
